(19) United States
(12) Patent Application Publication
(10) Pub. No.: US 2021/0151113 A1
(43) Pub. Date: May 20, 2021

(54) Memory Reading Speed Regulating Circuit

(71) Applicant: Shanghai Huali Microelectronics Corporation, Shanghai (CN)

(72) Inventor: Liang Hong, Shanghai (CN)

(73) Assignee: Shanghai Huali Microelectronics Corporation, Shanghai (CN)

(21) Appl. No.: 16/853,278

(22) Filed: Apr. 20, 2020

(30) Foreign Application Priority Data
Nov. 19, 2019 (CN) 201911133050.6

(51) Int. Cl. G11C 16/26; G11C 16/32

(52) U.S. Cl. CPC G11C 16/26; G11C 16/32

(57) ABSTRACT

The present invention discloses a memory reading speed regulating circuit, which uses a reading pulse to trigger an internal flag register to set to 1, and ensures that a data reading operation of a memory reading circuit is completed through a process that a reading operation completed pulse fed back by the memory reading circuit clears the value of the internal flag register to 0; when the reading operation is not completed within specified time, the value of the internal flag register is still 1, and a main controller speeds up the reading speed configuration of the memory reading circuit, and sends a rough regulation operation enable signal again to make a rough regulation judgment. The present invention can reduce the data reading power consumption of the memory and improve the reliability of the data reading operation.

### CROSS REFERENCE TO RELATED APPLICATIONS

The present application claims priority to and the benefit of Chinese Patent Application No. 201911133050.6 filed on Nov. 19, 2019, the disclosure of which is incorporated herein by reference in its entirety as part of the present application.

### BACKGROUND

The present invention relates to a storage technology, in particular to an adaptive memory reading speed regulating circuit applicable to nonvolatile memories.

In the existing nonvolatile memory technology, the timing control of the reading operation of the internal unit usually adopts an analog reading circuit design, and the schematic diagram is as illustrated in FIG. 1. Based on the given reference voltage or current, through a mirror circuit design, more accurate current is formed by using multiple analog switches to control the current, and through an analog delay circuit, internal accurate reading timing control is realized. By controlling these switches to be turned on and turned off, the configuration which enables the reading result to be correct can be found in the design.

Current controlled by this kind of switches is regulated from small to large, and the corresponding reading speed changes from slow to fast. The reading time of the nonvolatile memory is a key index. Generally, according to the regulation range controlled by this kind of switches, a reading process can be divided into three types of reading speed configurations, including reliable reading speed configuration, specified reading speed configuration and limit reading speed configuration.

The reliable reading speed configuration can ensure that other internal analog quantities (such as read comparison current) are correctly read without performing a fine regulation configuration. Under this configuration, the reading speed is lower than a design expected specification, but for an internal reading circuit, it can ensure more reliable reading of data. Under this speed configuration, the reading speed is slow and the power consumption is low.

The specified reading speed configuration provides reading speed that can satisfy the memory design specification under all conditions. Under this speed configuration, the reading speed satisfies the specifications and the power consumption is moderate.

The limit reading speed is a kind of reading speed which cannot satisfy that the reading operation is correct under all conditions, but can still obtain correct read data under specific conditions. For example, some circuits that cannot read correctly under low pressure and low temperature can read correct results under normal temperature and pressure. Under this speed configuration, the reading speed is fast and the power consumption is high.

From the perspective of application, what is needed is to obtain a correct result for each reading operation under use conditions. Generally, this demand is related to two factors, i.e., operating clock frequency, and environmental conditions such as voltage and current during the reading operation. Taking common mobile application scenarios as an example, under different scenarios, the requirements on the reading operation are different: under the standard operation, the required reading operation will be performed at the design standard speed, with high tolerance in power consumption; under the low power consumption mode, the overall system performance is reduced, and the requirements on the reading performance are greatly reduced, while it is required that the reading power consumption is greatly reduced.

In the prior art, the conventional method is to control the internal reading circuit of the nonvolatile memory by adopting the specified reading speed configuration. Generally, the reading speed configuration that can ensure the reading speed specification under different process angle conditions is selected. The resulting disadvantage is that all kinds of process angle, voltage and temperature influences need to be considered in the range of the reading operation configuration, which may cause the internal analog circuit to be configured at high performance, which is inconsistent with the actual application requirement, resulting in the waste of the actual power and performance.

As described above, regulating the reading speed in real time can bring the following benefits: first, it facilitates providing the performance configuration required by the application, and the power consumption of the memory and the system is reduced at the same time; second, for some chips with process defects, the workable state can be found under specific conditions, thus reducing the failure rate of the product.

### BRIEF SUMMARY

The technical problem to be solved by the present invention is to provide a memory reading speed regulating circuit, which can automatically regulate the data reading operation speed of the memory reading circuit, reduce the data reading power consumption of the memory and improve the reliability of the data reading operation.

In order to solve the above technical problem, the memory reading speed regulating circuit provided by the present invention comprises a main controller and a reading control circuit;

the reading control circuit comprises a reading operation controller, a reading operation circuit, a clock control circuit and an internal flag register;

the main controller, when a self-regulation operation enable end is in a trigger state, sends a rough regulation operation enable signal to the reading operation controller; and if an output configuration slow signal is received after the rough regulation operation enable signal is sent, outputs speeded-up reading control configuration information to a memory reading circuit, controls the reading speed configuration of the memory reading circuit to speed up, and sends the rough regulation operation enable signal to the reading operation controller again;

the reading operation controller, when the rough regulation operation enable signal is received, sends a rough regulation execution enable signal to the reading operation circuit and the clock control circuit;

the clock control circuit, when the rough regulation execution enable signal is received, sends an acquisition pulse to the reading operation circuit at a subsequent first system clock pulse trigger edge, and sends a reading pulse to the internal flag register and the memory reading circuit at a subsequent second system clock pulse trigger edge;

the internal flag register is set to 1 when a reading pulse trigger edge arrives and is cleared to 0 when a reading operation completed pulse fed back by the memory reading circuit is received;

the reading operation circuit, after the rough regulation execution enable signal sent by the reading operation controller is received, if the acquisition pulse sent by the clock control circuit is received, sends a rough reading address to the memory reading circuit;

the reading operation circuit, if the value of the internal flag register is 0 after a system clock cycle after the rough reading address is sent, outputs a configuration satisfy signal to the main controller, and otherwise outputs a configuration slow signal to the main controller;

the memory reading circuit, after the rough reading address is received, reads data according to the rough reading address when the reading pulse is received, and after reading is completed, outputs the reading operation completed pulse to the internal flag register.

Preferably, the main controller, after the rough regulation operation enable signal is sent, if the output configuration satisfy signal is received, ends a rough regulation stage, starts a fine regulation stage and sends a fine regulation operation enable signal to the reading operation controller; then if an output configuration fast signal is received, outputs speeded-down reading control configuration information to the memory reading circuit, controls the reading speed configuration of the memory reading circuit to speed down, and sends the fine regulation operation enable signal to the reading operation controller again;

the reading operation controller, when the fine regulation operation enable signal is received, sends a fine regulation execution enable signal to the reading operation circuit and the clock control circuit;

the clock control circuit, when the fine regulation execution enable signal is received, sends an acquisition pulse to the reading operation circuit at a subsequent first system clock pulse trigger edge, and sends a reading pulse to the internal flag register and the memory reading circuit at a subsequent second system clock pulse trigger edge;

the reading operation circuit, after the fine regulation execution enable signal is received, if the acquisition pulse sent by the clock control circuit is received, sends a fine reading address to the memory reading circuit;

the reading operation circuit, if the data read by the memory reading circuit after one system clock cycle after the fine reading address be sent is consistent with reference data, outputs a configuration satisfy signal to the main controller, and otherwise outputs a configuration fast signal to the main controller;

the memory reading circuit, after the fine reading address is received, reads the data according to the fine reading address when the reading pulse is received, sends the data to the reading operation circuit, and after reading is completed, outputs the reading operation completed pulse to the internal flag register.

Preferably, the main controller is capable of being set to a standard reading mode and a high-speed reading mode through a precise speed control end;

when the main controller enters the fine regulation stage and sends the fine regulation operation enable signal to the reading operation controller, if the output configuration satisfy signal is received:

if the main controller is set to the standard reading mode, the fine regulation under the standard reading mode is completed, and the current reading control configuration information is used as a standard reading control configuration;

if the main controller is set to the high-speed reading mode, speeded-up reading control configuration information is output to the memory reading circuit, the reading speed configuration of the memory reading circuit is controlled to speed up, the fine regulation operation enable signal is sent to the reading operation controller again, the fine regulation under the high-speed reading mode is completed until the main controller receives the output configuration fast signal, and the previous reading control configuration information is used as a high-speed reading control configuration;

the reading speed of the memory reading circuit under the high-speed reading control configuration is faster than the reading speed of the memory reading circuit under the standard reading control configuration.

Preferably, after the main controller enters the fine regulation stage and sends the fine regulation operation enable signal to the reading operation controller, when the output configuration fast signal is received, speeded-down reading control configuration information is output to the memory reading circuit, the reading speed configuration of the memory reading circuit is controlled to speed down, the fine regulation operation enable signal is sent to the reading operation controller again, the fine regulation is completed until the main controller receives the output configuration satisfy signal, and the current reading control configuration information is used as the reading control configuration of the current reading mode.

Preferably, after the memory reading speed regulating circuit is initialized, the self-regulation operation enable end of the main controller is in a standby state, the main controller outputs a reliable reading control configuration to the memory reading circuit, and controls the memory reading circuit to read the data according to the reliable reading control configuration;

the reading speed of the memory reading circuit under the reliable reading control configuration is slower than the reading speed of the memory reading circuit under the standard reading control configuration.

Preferably, the rough reading address is an address contained in the rough regulation execution enable signal, an address set in the reading operation circuit or an address randomly generated by the reading operation circuit.

Preferably, the fine reading address is an address contained in the fine regulation execution enable signal or an address set in the reading operation circuit.

Preferably, the fine reading address is the address of four physically distributed corners in the entire storage area of the memory.

Preferably, the reference data is reference data contained in the fine regulation execution enable signal or reference data set in the reading operation circuit.

Preferably, the main controller outputs the reading control configuration information to an analog self-regulating circuit which converts the reading control configuration information into an analog regulating quantity and sends the analog regulating quantity to the memory reading circuit, and controls the reading speed configuration of the memory reading circuit.

Preferably, the main controller, when the self-regulation operation enable end is in a standby state, controls the reading control circuit to stop working and outputs a reading control configuration result.

Preferably, the system clock pulse trigger edge, acquisition pulse trigger edge and reading pulse trigger edge are rising edges.

Preferably, the memory reading speed regulating circuit and the memory are integrated in the same chip.

Preferably, the memory reading speed regulating circuit is used as a peripheral circuit of the memory.

Preferably, the memory is a nonvolatile memory.

The memory reading speed regulating circuit provided by the present invention uses the reading pulse to trigger the internal flag register to set to 1, and ensures that the data reading operation of the memory reading circuit is completed through a process that the reading operation completed pulse fed back by the memory reading circuit clears the value of the internal flag register to 0; when the reading operation is completed within specified time, the value of the internal flag register remains at the original value 0; when the reading operation is not completed, the value of the internal flag register is still 1, and the main controller speeds up the reading speed configuration of the memory reading circuit, and sends the rough regulation operation enable signal again to make a rough regulation judgment. The memory reading speed regulating circuit, by judging whether the memory completes the reading operation within the specified time based on the value of the internal flag register and using the judgment result as a basis of regulating the analog reading circuit configuration of the memory, can adapt to automatically regulate the data reading operation speed of the memory reading circuit under different application scenarios, reduce the data reading power consumption of the memory and improve the reliability of the data reading operation.

### BRIEF DESCRIPTION OF THE DRAWINGS

In order to describe the technical solution of the present invention more clearly, the drawings required by the present invention will be briefly described below. Obviously, the drawings in the following description are only some embodiments of the present invention. One skilled in the art can obtain other drawings according to these drawings without contributing any inventive labor.

FIG. 1 is a schematic diagram of the existing memory timing control.

FIG. 2 is a schematic diagram of arrangement of reference units of a memory regulated by a memory reading speed regulating circuit according to the present invention.

FIG. 3 is a schematic diagram of a memory reading speed regulating circuit according to one embodiment of the present invention.

FIG. 4 is a schematic diagram of a reading control circuit of a memory reading speed regulating circuit according to one embodiment of the present invention.

FIG. 5 is a schematic diagram of an internal flag register of a memory reading speed regulating circuit according to one embodiment of the present invention.

FIG. 6 is a timing diagram of a working process of a memory reading speed regulating circuit according to one embodiment of the present invention.

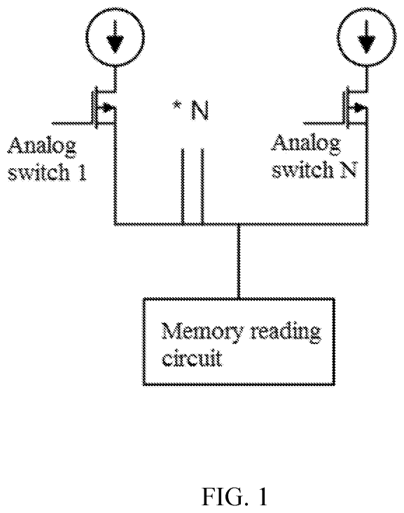

### DETAILED DESCRIPTION

The technical solution of the present invention will be clearly and completely described below with reference to the drawings. Obviously, the described embodiments are part of the embodiments of the present invention, instead of all of them. Based on the embodiments in the present invention, all other embodiments obtained by one skilled in the art without contributing any inventive labor shall fall into the protection scope of the present invention.

### Embodiment 1

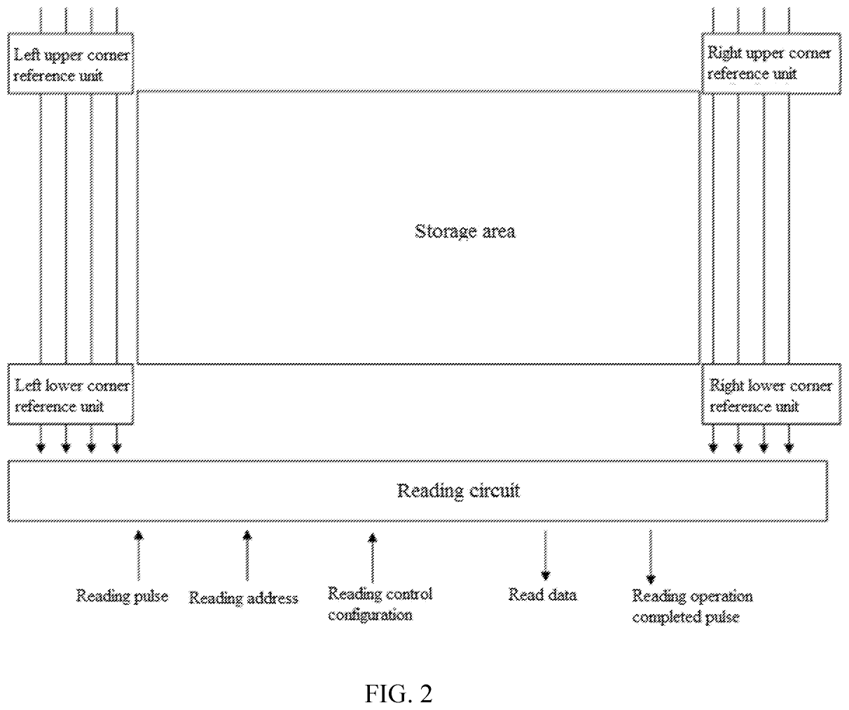

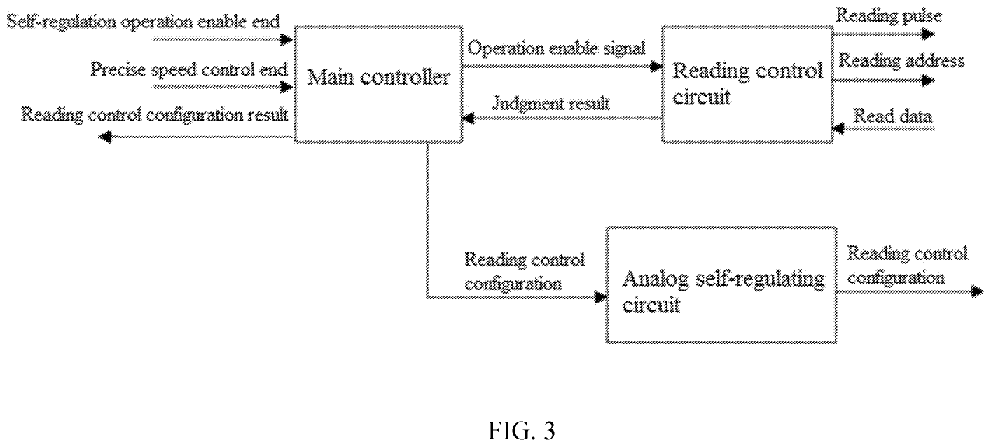

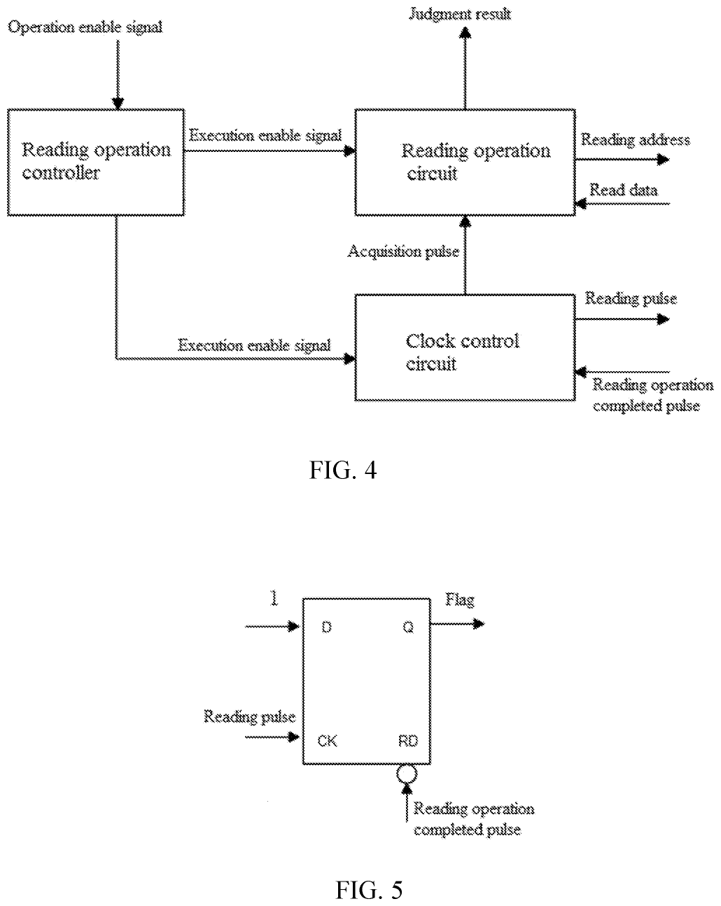

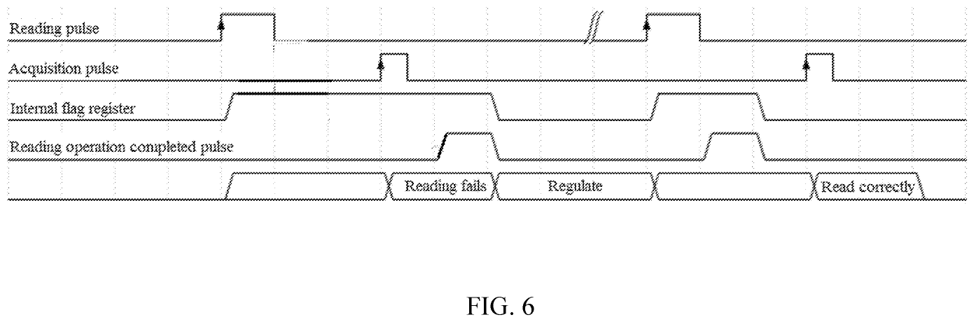

As illustrated in FIG. 2 to FIG. 6, the memory reading speed regulating circuit comprises a main controller and a reading control circuit;

the reading control circuit comprises a reading operation controller, a reading operation circuit, a clock control circuit and an internal flag register;

the main controller, when a self-regulation operation enable end is in a trigger state (for example, high-level state), sends a rough regulation operation enable signal to the reading operation controller; and if an output configuration slow signal is received after the rough regulation operation enable signal is sent, outputs speeded-up reading control configuration information to a memory reading circuit, controls the reading speed configuration of the memory reading circuit to speed up, and sends the rough regulation operation enable signal to the reading operation controller again;

the reading operation controller, when the rough regulation operation enable signal is received, sends a rough regulation execution enable signal to the reading operation circuit and the clock control circuit;

the clock control circuit, when the rough regulation execution enable signal is received, sends an acquisition pulse to the reading operation circuit at a subsequent first system clock pulse trigger edge, and sends a reading pulse to the internal flag register and the memory reading circuit at a subsequent second system clock pulse trigger edge;

the internal flag register is set to 1 when a reading pulse trigger edge arrives and is cleared to 0 when a reading operation completed pulse fed back by the memory reading circuit is received;

the reading operation circuit, after the rough regulation execution enable signal sent by the reading operation controller is received, if the acquisition pulse sent by the clock control circuit is received, sends a rough reading address to the memory reading circuit;

the reading operation circuit, if the value of the internal flag register is 0 after a system clock cycle after the rough reading address is sent, outputs a configuration satisfy signal to the main controller, and otherwise outputs a configuration slow signal to the main controller;

the memory reading circuit, after the rough reading address is received, reads data according to the rough reading address when the reading pulse is received, and after reading is completed, outputs the reading operation completed pulse to the internal flag register.

The memory reading speed regulating circuit according to embodiment 1 is a kind of reading speed regulating circuit based on the actual application environment, can regulate the reading speed of nonvolatile memories such as Flash based on the actual application scenario, and in the application with low performance requirements, can regulate the performance of the memory reading circuit, reduce the system reading power consumption and improve the reading reliability; in the application with high performance requirements, can improve the performance of the memory reading circuit and satisfy the high application requirements. The memory reading speed regulating circuit uses the reading pulse to trigger the internal flag register to set to 1, and ensures that the data reading operation of the memory reading circuit is completed through a process that the reading operation completed pulse fed back by the memory reading circuit clears the value of the internal flag register to 0; when the reading operation is completed within specified time (a system clock cycle), the value of the internal flag register remains at the original value 0; when the reading operation is not completed, the value of the internal flag register is still 1, which indicates that the reading speed configuration of the memory reading circuit is slow, and the main controller speeds up the reading speed configuration of the memory reading circuit, and sends the rough regulation operation enable signal again to make a rough regulation judgment. The memory reading speed regulating circuit, by judging whether the memory completes the reading operation within the specified time based on the value of the internal flag register and using the judgment result as a basis of regulating the analog reading circuit configuration of the memory, can adapt to automatically regulate the data reading operation speed of the memory reading circuit under different application scenarios, reduce the data reading power consumption of the memory and improve the reliability of the data reading operation.

### Embodiment 2

Based on the memory reading speed regulating circuit according to embodiment 1, the main controller, after the rough regulation operation enable signal is sent, if the output configuration satisfy signal is received, ends a rough regulation stage, starts a fine regulation stage and sends a fine regulation operation enable signal to the reading operation controller; then if an output configuration fast signal is received, outputs speeded-down reading control configuration information to the memory reading circuit, controls the reading speed configuration of the memory reading circuit to speed down, and sends the fine regulation operation enable signal to the reading operation controller again;

the reading operation controller, when the fine regulation operation enable signal is received, sends a fine regulation execution enable signal to the reading operation circuit and the clock control circuit;

the clock control circuit, when the fine regulation execution enable signal is received, sends an acquisition pulse to the reading operation circuit at a subsequent first system clock pulse trigger edge, and sends a reading pulse to the internal flag register and the memory reading circuit at a subsequent second system clock pulse trigger edge;

the reading operation circuit, after the fine regulation execution enable signal is received, if the acquisition pulse sent by the clock control circuit is received, sends a fine reading address to the memory reading circuit;

the reading operation circuit, if the data read by the memory reading circuit after one system clock cycle after the fine reading address be sent is consistent with reference data, outputs a configuration satisfy signal to the main controller, and otherwise outputs a configuration fast signal to the main controller;

the memory reading circuit, after the fine reading address is received, reads the data according to the fine reading address when the reading pulse is received, sends the data to the reading operation circuit, and after reading is completed, outputs the reading operation completed pulse to the internal flag register.

In the memory reading speed regulating circuit according to embodiment 2, the main controller controls the reading control circuit to adaptively regulate the reading speed of the memory through two processes, i.e., rough regulation and fine regulation; in the fine regulation process, the memory reading circuit reads the target data in the specific address, compares whether the target data in the specific address of the memory is consistent with the reference data, if not, controls the reading speed configuration of the memory reading circuit to speed down to ensure that the data in the memory can be read accurately.

### Embodiment 3

Based on the memory reading speed regulating circuit according to embodiment 2, the main controller is capable of being set to a standard reading mode and a high-speed reading mode through a precise speed control end;

when the main controller enters the fine regulation stage and sends the fine regulation operation enable signal to the reading operation controller, if the output configuration satisfy signal is received:

if the main controller is set to the standard reading mode, the fine regulation under the standard reading mode is completed, and the current reading control configuration information is used as a standard reading control configuration;

if the main controller is set to the high-speed reading mode, speeded-up reading control configuration information is output to the memory reading circuit, the reading speed configuration of the memory reading circuit is controlled to speed up, the fine regulation operation enable signal is sent to the reading operation controller again, the fine regulation under the high-speed reading mode is completed until the main controller receives the output configuration fast signal, and the previous reading control configuration information is used as a high-speed reading control configuration;

the reading speed of the memory reading circuit under the high-speed reading control configuration is faster than the reading speed of the memory reading circuit under the standard reading control configuration.

Preferably, after the main controller enters the fine regulation stage and sends the fine regulation operation enable signal to the reading operation controller, when the output configuration fast signal is received, which indicates that the reading speed of the memory reading circuit is fast and cannot satisfy the actual reliable reading requirement of the reading circuit, speeded-down reading control configuration information is output to the memory reading circuit, the reading speed configuration of the memory reading circuit is controlled to speed down, the fine regulation operation enable signal is sent to the reading operation controller again, the fine regulation is completed until the main controller receives the output configuration satisfy signal, and the current reading control configuration information is used as the reading control configuration of the current reading mode.

The memory reading speed regulating circuit according to embodiment 3 can be set to the standard reading mode or high-speed reading mode through the precise speed control end of the main controller and the reading control configuration of the memory reading circuit is performed according to different reading modes, such that the memory reading result is more reliable.

In the low-power application, the memory reading speed regulating circuit according to embodiment 3 can reduce the power consumption of the system analog circuit and increase the reliability of the reading circuit by regulating the reading control configuration of the memory reading circuit with the decrease of the system clock. In the standard-performance application, the memory reading speed regulating circuit according to embodiment 3 can accurately obtain the reading speed that satisfies the application condition, thus avoiding the waste of performance and power.

### Embodiment 4

Based on the memory reading speed regulating circuit according to embodiment 3, after the memory reading speed regulating circuit is initialized, the self-regulation operation enable end of the main controller is in a standby state (for example, low-level state), the main controller outputs a reliable reading control configuration to the memory reading circuit, and controls the memory reading circuit to read the data according to the reliable reading control configuration;

the reading speed of the memory reading circuit under the reliable reading control configuration is slower than the reading speed of the memory reading circuit under the standard reading control configuration.

Preferably, the main controller, when the self-regulation operation enable end is in a standby state (for example, low-level state), controls the reading control circuit to stop working and outputs a reading control configuration result (a reading control configuration result under the standard reading mode and a reading control configuration result under the high-speed reading mode).

Preferably, the main controller outputs the reading control configuration information to an analog self-regulating circuit which converts the reading control configuration information into an analog regulating quantity and sends the analog regulating quantity to the memory reading circuit, and controls the reading speed configuration of the memory reading circuit.

Preferably, the rough reading address is an address contained in the rough regulation execution enable signal, an address set in the reading operation circuit or an address randomly generated by the reading operation circuit.

Preferably, the fine reading address is an address contained in the fine regulation execution enable signal or an address set in the reading operation circuit.

Preferably, the fine reading address is the address of four physically distributed corners in the entire storage area of the memory.

Preferably, the reference data is reference data contained in the fine regulation execution enable signal or reference data set in the reading operation circuit.

Preferably, the system clock pulse trigger edge, acquisition pulse trigger edge and reading pulse trigger edge are rising edges.

Preferably, the memory reading speed regulating circuit and the memory are integrated in the same chip.

Preferably, the memory reading speed regulating circuit is used as a peripheral circuit of the memory.

Preferably, the memory is a nonvolatile memory.

The above embodiments are only preferred embodiments of the present invention and are not used for limiting the present invention. Any modifications, equivalent replacements, improvements and the like shall be included in the protection scope of the present invention.

What is claimed is:

1. A memory reading speed regulating circuit, wherein the memory reading speed regulating circuit comprises a main controller and a reading control circuit;
the reading control circuit comprises a reading operation controller, a reading operation circuit, a clock control circuit and an internal flag register;
the main controller, when a self-regulation operation enable end is in a trigger state, sends a rough regulation operation enable signal to the reading operation controller; and if an output configuration slow signal is received after the rough regulation operation enable signal is sent, outputs speeded-up reading control configuration information to a memory reading circuit, controls the reading speed configuration of the memory reading circuit to speed up, and sends the rough regulation operation enable signal to the reading operation controller again;
the reading operation controller, when the rough regulation operation enable signal is received, sends a rough regulation execution enable signal to the reading operation circuit and the clock control circuit;
the clock control circuit, when the rough regulation execution enable signal is received, sends an acquisition pulse to the reading operation circuit at a subsequent first system clock pulse trigger edge, and sends a reading pulse to the internal flag register and the memory reading circuit at a subsequent second system clock pulse trigger edge;
the internal flag register is set to 1 when a reading pulse trigger edge arrives and is cleared to 0 when a reading operation completed pulse fed back by the memory reading circuit is received;
the reading operation circuit, after the rough regulation execution enable signal sent by the reading operation controller is received, if the acquisition pulse sent by the clock control circuit is received, sends a rough reading address to the memory reading circuit;
the reading operation circuit, if the value of the internal flag register is 0 after a system clock cycle after the rough reading address is sent, outputs a configuration satisfy signal to the main controller, and otherwise outputs a configuration slow signal to the main controller;
the memory reading circuit, after the rough reading address is received, reads data according to the rough reading address when the reading pulse is received, and after reading is completed, outputs the reading operation completed pulse to the internal flag register.

2. The memory reading speed regulating circuit according to claim 1, wherein
the main controller, after the rough regulation operation enable signal is sent, if the output configuration satisfy signal is received, ends a rough regulation stage, starts a fine regulation stage and sends a fine regulation operation enable signal to the reading operation controller; then if an output configuration fast signal is received, outputs speeded-down reading control configuration information to the memory reading circuit, controls the reading speed configuration of the memory reading circuit to speed down, and sends the fine regulation operation enable signal to the reading operation controller again;
the reading operation controller, when the fine regulation operation enable signal is received, sends a fine regulation execution enable signal to the reading operation circuit and the clock control circuit;
the clock control circuit, when the fine regulation execution enable signal is received, sends an acquisition pulse to the reading operation circuit at a subsequent first system clock pulse trigger edge, and sends a reading pulse to the internal flag register and the memory reading circuit at a subsequent second system clock pulse trigger edge;
the reading operation circuit, after the fine regulation execution enable signal is received, if the acquisition pulse sent by the clock control circuit is received, sends a fine reading address to the memory reading circuit;
the reading operation circuit, if the data read by the memory reading circuit after one system clock cycle after the fine reading address be sent is consistent with reference data, outputs a configuration satisfy signal to the main controller, and otherwise outputs a configuration fast signal to the main controller;
the memory reading circuit, after the fine reading address is received, reads the data according to the fine reading address when the reading pulse is received, sends the data to the reading operation circuit, and after reading is completed, outputs the reading operation completed pulse to the internal flag register.

3. The memory reading speed regulating circuit according to claim 2, wherein
the rough reading address is an address contained in the rough regulation execution enable signal, an address set in the reading operation circuit or an address randomly generated by the reading operation circuit.

4. The memory reading speed regulating circuit according to claim 2, wherein
the fine reading address is an address contained in the fine regulation execution enable signal or an address set in the reading operation circuit.

5. The memory reading speed regulating circuit according to claim 2, wherein
the fine reading address is the address of four physically distributed corners in the entire storage area of the memory.

6. The memory reading speed regulating circuit according to claim 2, wherein
the reference data is reference data contained in the fine regulation execution enable signal or reference data set in the reading operation circuit.

7. The memory reading speed regulating circuit according to claim 1, wherein
the main controller is capable of being set to a standard reading mode and a high-speed reading mode through a precise speed control end;
when the main controller enters the fine regulation stage and sends the fine regulation operation enable signal to the reading operation controller, if the output configuration satisfy signal is received:
if the main controller is set to the standard reading mode, the fine regulation under the standard reading mode is completed, and the current reading control configuration information is used as a standard reading control configuration;
if the main controller is set to the high-speed reading mode, speeded-up reading control configuration information is output to the memory reading circuit, the reading speed configuration of the memory reading circuit is controlled to speed up, the fine regulation operation enable signal is sent to the reading operation controller again, the fine regulation under the high-speed reading mode is completed until the main controller receives the output configuration fast signal, and the previous reading control configuration information is used as a high-speed reading control configuration;
the reading speed of the memory reading circuit under the high-speed reading control configuration is faster than the reading speed of the memory reading circuit under the standard reading control configuration.

8. The memory reading speed regulating circuit according to claim 7, wherein
after the main controller enters the fine regulation stage and sends the fine regulation operation enable signal to the reading operation controller, when the output configuration fast signal is received, speeded-down reading control configuration information is output to the memory reading circuit, the reading speed configuration of the memory reading circuit is controlled to speed down, the fine regulation operation enable signal is sent to the reading operation controller again, the fine regulation is completed until the main controller receives the output configuration satisfy signal, and the current reading control configuration information is used as the reading control configuration of the current reading mode.

9. The memory reading speed regulating circuit according to claim 7, wherein
after the memory reading speed regulating circuit is initialized, the self-regulation operation enable end of the main controller is in a standby state, the main controller outputs a reliable reading control configuration to the memory reading circuit, and controls the memory reading circuit to read the data according to the reliable reading control configuration;
the reading speed of the memory reading circuit under the reliable reading control configuration is slower than the reading speed of the memory reading circuit under the standard reading control configuration.

10. The memory reading speed regulating circuit according to claim 1, wherein
the main controller outputs the reading control configuration information to an analog self-regulating circuit which converts the reading control configuration information into an analog regulating quantity and sends the analog regulating quantity to the memory reading circuit, and controls the reading speed configuration of the memory reading circuit.

11. The memory reading speed regulating circuit according to claim 1, wherein
the main controller, when the self-regulation operation enable end is in a standby state, controls the reading control circuit to stop working and outputs a reading control configuration result.

12. The memory reading speed regulating circuit according to claim 1, wherein
the system clock pulse trigger edge, acquisition pulse trigger edge and reading pulse trigger edge are rising edges.

13. The memory reading speed regulating circuit according to claim 1, wherein
the memory reading speed regulating circuit and the memory are integrated in the same chip.

14. The memory reading speed regulating circuit according to claim 1, wherein
the memory reading speed regulating circuit is used as a peripheral circuit of the memory.

15. The memory reading speed regulating circuit according to claim 1, wherein
the memory is a nonvolatile memory.
